(19) United States
(12) Patent Application Publication
(10) Pub. No.: US 2020/0075651 A1
(43) Pub. Date: Mar. 5, 2020

(54) DOUBLE-LAYER COLOR FILTER AND METHOD FOR FORMING THE SAME

(71) Applicant: HUAIAN IMAGING DEVICE MANUFACTURER CORPORATION, Jiangsu (CN)

(72) Inventors: DongLiang ZHANG, Jiangsu (CN); Kishou KANEKO, Jiangsu (CN); XiaoLu HUANG, Jiangsu (CN)

(21) Appl. No.: 16/517,014

(22) Filed: Jul. 19, 2019

(30) Foreign Application Priority Data
Aug. 28, 2018 (CN) 201810987587.8

(51) Int. Cl. H01L 27/146; H01L 27/30

(52) U.S. Cl. CPC H01L 27/14621; H01L 27/14685; H01L 27/307; H01L 27/14629

(57) ABSTRACT

The disclosure discloses a method of forming a double-layer color filter device and the structure of the color filter in an image sensor. The method includes: providing a photosensitive unit on a substrate; forming a first color filter layer on the photosensitive unit; etching the first color filter layer, to form a first filter having a first convex contour; and forming a second color filter layer on the first convex contour of the first filter, and etching the second color filter layer, to form a second filter having a second convex contour.

### CROSS REFERENCE TO RELATED APPLICATION

This application claims the benefits of priority to Chinese Patent Application No. CN 201810987587.8, entitled “Double-Layer Color Filter and Method for Forming Double-Layer Color Filter”, filed with CNIPA on Aug. 28, 2018, the contents of which are incorporated herein by reference in its entirety

### TECHNICAL FIELD

The present disclosure relates to the field of semiconductor technologies, and in particular, to a double-layer color filter and a method for forming a double-layer color filter.

### BACKGROUND

Image sensors are widely applied to various technology fields. In brief, an image sensor is an integrated photoelectric device in which a plurality of photosensitive units and an electronic circuitry converting optical to electronic signals are formed on the same wafer substrate. Each photosensitive unit converts light image signals based on intensity received by the photosensitive unit into a series of electrical signals. A large quantity of photosensitive unit work together. Two dimensional optical images that are incident on the photosensitive surface of an image sensor are converted into electric signal “images” output in a time sequence. These electric signals are suitably processed to reproduce the incident optical images.

An image sensor may apply a charge-coupled device (CCD) and a complementary metal oxide semiconductor image sensor (CIS). A CIS typically includes a solid-state image device, a filter, and a microlens, etc. An existing image sensor consists of a pixel array of photosensors. Each pixel, upon receiving incident light, generates an electric signal corresponding to the incident light, the magnitude of the electric signal generated by each pixel being proportional to the amount of incident light irradiating on the photosensor. A filter is disposed above the solid-state photosensor, and a microlens is formed on the filter, so that incident light passes through the filter and is refracted on the photosensor. However, usually a large quantity of incident light ray does not directly reach the photosensor from loss in scattering, resulting in low sensitivity of a solid-state image.

Spectral crosstalk among various wavelengths is a problem that occurs in imaging devices. Often image sensors are prone to spectral crosstalk in operation if only one layer of filters is provided. When a small portion of optical power that should reach specific color channels actually enters another color channel, spectral crosstalk occurs, and consequently, a final imaging result is degraded. Therefore, to increase the amount of light rays received by image sensors and reduce spectral crosstalks have become an urgent problem to solve in the manufacture of the image sensors.

### SUMMARY

The present disclosure is proposed to provide a double-layer color filter and a method for making the same According to the present disclosure, The present disclosure provides a method for forming double-layer color filter on a solid-state image device, comprising: providing a photosensitive unit on a substrate; forming a first color filter layer on the photosensitive unit; etching the first color filter layer, to form a first filter having a first convex contour; and forming a second color filter layer on the first convex contour of the first filter, and etching the second color filter layer, to form a second filter having a second convex contour.

Preferably, the first filter has a first refractive index, the second filter has a second refractive index, and wherein the first refractive index is different from the second refractive index.

Preferably, the first refractive index of the first filter and the second refractive index of the second filter are both in a range of 1.6 to 1.7.

Preferably, the first color filter layer is formed on the solid-state image device by spin coating, and the second color filter layer is formed on the first convex contour of the first filter by spin coating.

Preferably, the first convex contour and the second convex contour are formed by wet etching or dry etching, and wherein an edge etch rate and a center etch rate of the first convex contour are different, and wherein an edge etch rate and a center etch rate of the second convex contour are different.

The present disclosure further provided a double-layer color filter device for a solid-state image device, comprising a plurality of double-layer color filters mounted on photosensitive units on a substrate, wherein each of the plurality of double-layer color filters comprises: a first filter and a second filter conforming to the first filter, and wherein each of the plurality of double-layer color filters is aligned one-to-one to a pixel area of one of the photosensitive units, wherein the photosensitive units each is a solid-state image device.

Preferably, the first filter has a first refractive index, and the second filter has a second refractive index, wherein the second refractive index is different from the first refractive index.

Preferably, an upper surface of the first filter has a first curve, and an upper surface of the second filter has a second curve

Preferably, materials of the first filter and the second filter are different organic materials.

Preferably, the first filter and the second filter aligned to a same photosensitive unit and pass the same color light.

### BRIEF DESCRIPTION OF THE DRAWINGS

FIG. 1 is a schematic diagram of a conventional image sensor having a filter and a microlens.

FIG. 2 is a schematic diagram of double-layer color filters in an image sensor according to one embodiment of the current disclosure.

FIGS. 3 to 7 are schematic diagrams of steps in forming a double-layer color filter according to a method of the present disclosure.

FIG. 8 is a schematic diagram of double-layer color filters in an image sensor according to another embodiment of the current disclosure.

FIG. 9 is a schematic diagram of double-layer color filters according to still another embodiment of the present disclosure.

### DESCRIPTION FOR REFERENCE NUMERALS

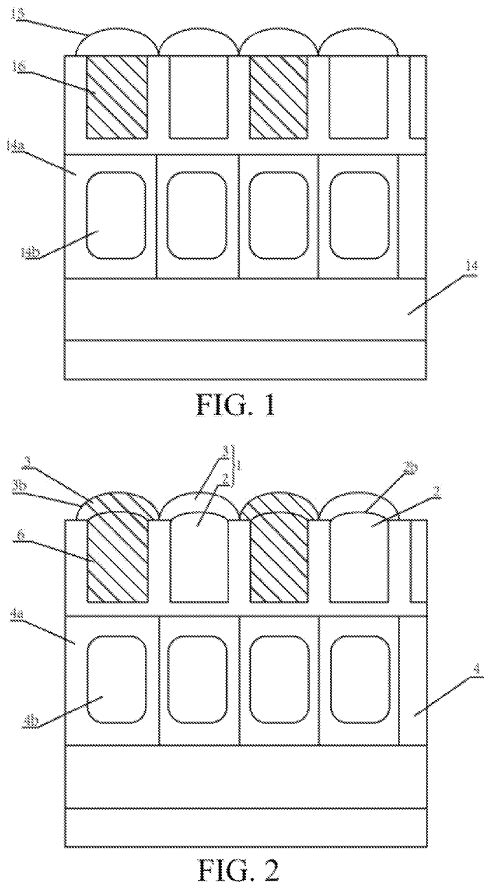

In FIG. 1

14—solid-state image device; 14a—pixel area; 14b—photosensitive device; 15—microlens; 16—filter.

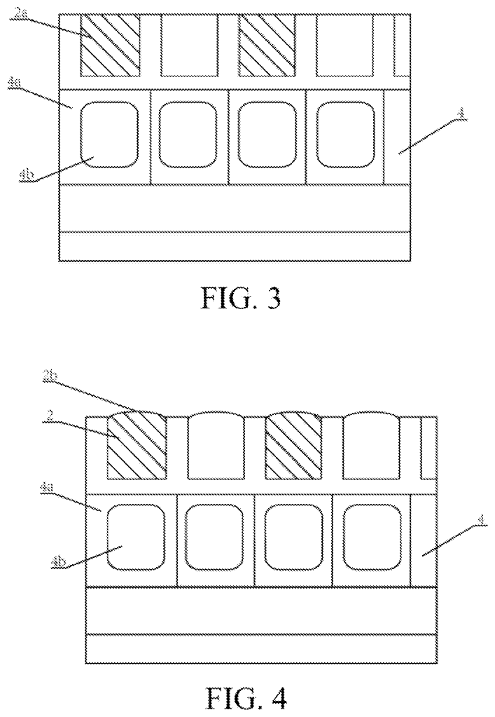

In FIGS. 2 to 9

1—double-layer color filter; 2—first filter; 2a—first color filter layer; 2b—first convex contour; 3—second filter; 3a—second color filter layer; 3b—second convex contour; 4—solid-state image device; 4a—pixel area; 4b—photosensitive device; 5—microlens; 6—filter.

### DETAILED DESCRIPTION OF THE PREFERRED EMBODIMENTS

The present disclosure is further described in detail below with reference to the accompanying drawings of the specification. A structure of an image sensor and the like are schematically simplified and shown in the accompanying drawings.

Patterns of the present disclosure and some features, advantages, and details are more fully described below with reference to non-limitative embodiments shown in the accompanying drawings. Detailed descriptions of existing well-known materials, manufacturing tools, process technologies, and the like are omitted, to avoid unnecessary excessive details. However, it should be understood that although various patterns of the present disclosure are specified in detailed descriptions and specific embodiments, the patterns are shown by way of example and are not used as a limitation. Various replacements, modifications, additions, and/or arrangements of the present disclosure and the spirit and/or scope based on concepts of the present disclosure are obvious to a person skilled in the art.

Approximate languages, as used throughout the specification and claims herein, can be used to modify any quantitative expression that is allowed to change so as not to change basic functions involved therein. Therefore, values modified by one or more terms such as “approximately” are not limited to specified accurate values. In some cases, approximate languages may correspond to accuracy measurement values of an instrument.

Terms used in this text are merely for the purpose of describing particular embodiments and are not intended to limit the present disclosure. As used in this text, single forms “a”, “an” and “the” are intended to include plural forms as well, unless otherwise specified in the context clearly. It is further understood that terms “consist of” (and any form of “consist of”, for example, “compose” and “comprise”), “have” (and any form of “have”, for example, “possess” and “own”), “include” (and any form of “include”, for example, “comprise” and “contain”), and “comprise” (and any form of “comprise”, for example, “include” and “contain”) are open link verbs. A result is that a method or device “including”, “having”, “containing”, or “comprising” one or more steps or elements means owning the one or more steps or elements but is not limited to merely owning the one or more steps or elements.

As used in this text, a term that is used to indicate “connection” between two physical elements refers to direct connection between two physical elements, and a term “coupling” may be direct connection or connection through one or more intermediate elements.

As used in this text, terms “may” and “may be” indicate a possibility of occurrence in a group of cases, one having an attribute, property, or function, and/or modifying another verb by expressing one or more modified verbs related to capability, performance, and possibility. Therefore, the use of “may” and “may be” means that a modified term is apparently appropriate, capable, or suitable for a specified ability, function, or use. Although it is considered, the modified term may sometimes not be appropriate, capable, or suitable in some cases. For example, in some cases, an event or capability may be expected, while in other cases, the event or capability cannot occur—the difference is captured by the terms “may” and “may be”.

As described in the Background, a filter 16 in a conventional image sensor is usually made behind a number of microlens 15, so that light rays are focused and filtered. However, because a filtering effect of the filter 6 on light is limited to narrow range of wavelengths, spectral crosstalks easily occur.

In brief, referring to FIG. 1, major steps of forming the filter 16 and the microlens 15 comprise: forming a color filter layer on a solid-state image device 14; forming a microlens layer on the color filter layer; and etching the microlens layer, to form a plurality of microlenses 15 distributed in an array.

Specifically, a color filter material is spin-coated on the solid-state image device 14 and is exposed and developed, to form a color filter layer capable of passing color light. Afterwards, a photoresist mask is formed on the color filter layer, and the color filter layer is then etched, until an upper surface of the solid-state image device 14 is exposed. Another color filter material is then spin-coated at other positions on the solid-state image device 14, and is exposed and developed to form a new color filter layer capable of passing another color light. A step of forming a filter layer that allows other color light to pass through is the same as the foregoing step, and differs from the foregoing step only in that a material for spin coating may vary according to colors of light that needs to be absorbed. In addition, a plurality of pixel areas 14a is divided on the solid-state image device 14, each pixel area 14a is correspondingly provided with a photosensitive device 14b, and the filter 16 is correspondingly disposed on the photosensitive device 14b (such as a photodiode) in the solid-state image device 14.

After a color filter layer is formed on the upper surface of the solid-state image device 14, the upper surface is processed by means of chemical mechanical polishing, so that the upper surface of the color filter layer is smooth, and the filter 16 is formed. Then a microlens material layer (such as a transparent resin) is deposited on an upper surface of the filter 16, a photoresist layer is formed on the microlens material layer, and the photoresist layer is exposed and developed, to form microlens graphs arranged at intervals. Using the photoresist layer as a mask, the microlens material layer is etched along the microlens graphs, to form microlenses 15 arranged at intervals. Then, a reflux process is used, so that a surface of the microlens 15 becomes raised. The position of each microlens 15 corresponds to that of the photosensitive device 14b, and the width of the microlens 15 is greater than or equal to the width of the corresponding photosensitive device 14b. In other embodiments, when the microlens 15 is formed by applying a photoetching process, a mask plate with gradual light transmittance is used, so that an exposed photoresist has different thicknesses, and etching amounts of the edge and the center with different thicknesses of the microlens 15 are realized in a subsequent etching process, so that the microlens 15 with a raised surface is formed.

After light rays irradiate a surface of the microlens 15, the light rays are refracted by the microlens 15, so that a light path is changed, the light rays are gradually gathered, and the gathered light rays continue to propagate in the filter 16. Since the filter 16 is selective for light of different wavelengths, it is possible to allow light of one color to pass through the filter 16 and absorb or block light of other colors.

However, the conventional image sensor can selectively pass incident light only through one layer of filter 16, thereby causing spectral crosstalk due to imperfect color filtering. For example, a blue filter can pass blue light while also passing a part of red and green light, so that a pixel coupled to the blue filter receives not only the blue light that the pixel need to receive, but also a part of red or green light. In a CMOS image sensor, crosstalk causes spatial resolution degradation, color mixing, and image noise. Therefore, a signal to noise ratio (SNR) of a sensor and an error rate of a system are affected. In an RGB image sensor, although sensitivity can be obtained by using the filter 16, crosstalk is increased.

In addition, some other types of crosstalk can be reduced by processing profile control between pixels. A way of reducing spectral crosstalk is to increase pigment concentration of the filter 16, but undesirable refractive index of a material changes.

### Embodiment 1

To resolve the foregoing problem, the first embodiment provides a method for forming a double-layer color filter 1. Referring to FIGS. 2 to 7, the method for forming the double-layer color filter 1 according to the present disclosure comprises: providing a solid-state image device 4 and forming a first color filter layer 2a on the solid-state image device 4; etching the first color filter layer 2a, to form a first filter 2 having a first convex contour 2b; and forming a second color filter layer 3a on the first convex contour 2b of the first filter 2, and etching the second color filter layer 3a, to form a second filter 3 having a second convex contour 3b, to form the double-layer color filter 1 having the first filter 2 and the second filter 3. The color filter may be various filters such as a red, a green, or a blue filter. To distinguish filters, a filter with shadow lines and a filter with no shadow lines in the figures represent filters of different colors.

In brief, in the present disclosure, the first filter 2 is formed on the solid-state image device 4, and the second filter 3 is formed on the first filter 2. Passing of light rays is selected through the double-layer filters, to improve color filtering and avoid occurrence of spectral crosstalk. In addition, the first convex contour 2b and the second convex contour 3b are formed by means of etching, to effectively enhance a light concentration effect, thereby increasing an admitted light amount.

Preferably, in this embodiment, the first color filter layer 2a and the second color filter layer 3a may be formed by selecting different materials. The first filter 2 is formed by etching the first color filter layer 2a, and the second color filter layer 3a has a first refractive index, the second filter 3 formed through etching has a second refractive index, and the first refractive index is different from the second refractive index.

The first filter 2 and the second filter 3 having different refractive indexes are formed, so that a propagation path of light rays in the filter can be designed, and an angle of view of the double-layer color filter 1 can be effectively increased, thereby increasing an admitted light amount.

Although the first filter 2 and the second filter 3 are of different materials, a characteristic that the first filter 2 and the second filter 3 can pass light of the same color can improve performance of selection of the filter for light rays. For example, when the first filter 2 is a red filter, the second filter 3 is also a red filter, to ensure that red light rays can be received by a corresponding photosensor on the solid-state image device 4 after passing through the first filter 2 and the second filter 3.

More preferably, in this embodiment, a material whose refractive index is within a range of 1.6 to 1.7 is selected, so that the first refractive index of the first filter 2 and the second refractive index of the second filter 3 are set to be 1.6 to 1.7.

The first refractive index and the second refractive index are set to be 1.6 to 1.7, so that refraction of light rays is controlled within a reasonable range, thereby preventing spectral crosstalk caused by excessive deflection of light rays.

In addition, preferably, the first color filter layer 2a is formed on the solid-state image device 4 by spin coating, and the second color filter layer 3a is formed on the first convex contour 2b of the first filter 2 by spin coating.

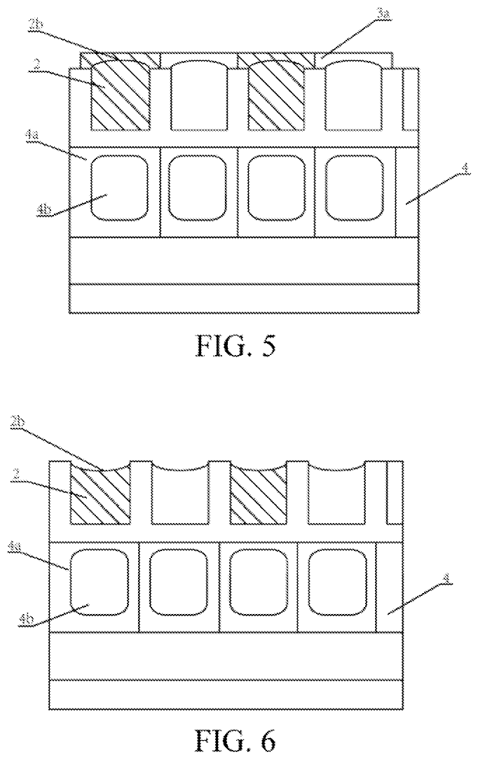

Specifically, referring to FIG. 3 and FIG. 4, materials forming the first color filter layer 2a and the second color filter layer 3a are organic compounds with colors. Coating the organic compounds on the surface of the solid-state image device 4 during spin coating usually comprises: four steps of droplet separation, rotation and spreading, rotation and detachment, and solvent volatilization, to form an organic compound layer on the surface of the solid-state image device 4. The first color filter layer 2a and the second color filter layer 3a are formed by means of spin coating, to ensure that surfaces of the two filter layers are smooth and closely fit and help improve forming accuracy of the formed first convex contour 2b and second convex contour 3b.

Preferably, in this embodiment, the first convex contour 2b and the second convex contour 3b are formed by means of wet etching or dry etching, and an edge etch rate and a center etch rate of the first convex contour 2b are different, and an edge etch rate and a center etch rate of the second convex contour 3b are different.

According to a method for adjusting the etch rate, etching depths on the first color filter layer 2a and the second color filter layer 3a can be adjusted, so that the first convex contour 2b and the second convex contour 3b having radians are formed.

Specifically, referring to FIGS. 2 to 5, in this embodiment, the step of forming the first filter 2 and the second filter 3 is:

spin-coating a first organic compound on the solid-state image device 4, to form the first color filter layer 2a;

placing the solid-state image device 4 into a photoetching machine, and exposing the solid-state image device 4 through blocking by a mask plate;

removing the first organic compound redundant on the first color filter layer 2a by using a developing process, to form several modules corresponding to the position of the photosensitive device 4b in the solid-state image device 4;

etching each module on the first color filter layer 2a by using an etching machine, and forming a plurality of first filters 2 having the first convex contour 2b by adjusting an etching depth;

spin-coating a second organic compound on a surface consisting of the plurality of first filters 2, to form the second color filter layer 3a; placing the solid-state image device 4 into a photoetching machine, and exposing the solid-state image device 4 through blocking by a mask plate;

removing the second organic compound redundant on the second color filter layer 3a by using a developing process, to form several modules corresponding to the positions of the first filters 2; and

etching each module on the second color filter layer 3a by using an etching machine, and forming a plurality of second filters 3 having the second convex contour 3b by adjusting an etching depth.

In addition, in this embodiment, the etch rate is respectively adjusted according to the needed first refractive index of the first filter 2 and the needed second refractive index of the second filter 3. Specifically, when the first refractive index and the second refractive index are different, to ensure the admitted light amount, the direction toward which the first convex contour 2b and second convex contour 3b are raised changes. Therefore, when the etching step is performed, the etch rate needs to be adjusted to form different etching depths. When the first refractive index of the first filter 2 is greater than the second refractive index of the second filter 3, the first convex contour 2b is formed to be raised toward the photosensitive device 4b, and the edge etch rate is less than the central etch rate. When the first refractive index is less than the second refractive index, the first convex contour 2b is formed to be raised outward, and the edge etch rate is greater than the central etch rate.

Specifically, referring to FIG. 6 to FIG. 9, when the first refractive index is less than the second refractive index, the edge etch rates of the first convex contour 2b and the second convex contour 3b may be adjusted to be greater than the central etch rate, to form the first convex contour 2b and the second convex contour 3b that are raised outward.

When the first refractive index is greater than the second refractive index, the edge etch rates of the first convex contour 2b and the second convex contour 3b may be adjusted to be less than the central etch rate, to form the first convex contour 2b and the second convex contour 3b that are raised toward the photosensitive device 4b. The edge etch rate may be adjusted to be less than the central etch rate when the first convex contour 2b is etched, and the edge etch rate may be adjusted to be greater than the central etch rate when the second convex contour 3b is etched, to form the first convex contour 2b raised toward the photosensitive device 4b and the second convex contour 3b raised outward, that is, surfaces of the first filter 2 and the second filter 3 are raised outward.

It should be noted that an operation step of chemical or mechanical polishing may be performed on the first color filter layer 2a and the second color filter layer 3a before etching, so that surfaces are smooth, to ensure that the formed first filter 2 and second filter 3 are both of symmetric structures, ensuring optical performance of the filters.

It should be noted that in this embodiment, the first filter 2 and the second filter 3 may be formed in red, green, or blue, but the aligned first filter 2 and second filter 3 on the same photosensor are formed in the same color.

In conclusion, in the present disclosure, the first filter 2 with the first convex contour 2b and the second filter 3 with the second convex contour 3b are formed on the solid-state image device 4. In addition, the double-layer filter can more effectively focus and filter color light. Therefore, in the method for forming a double-layer color filter 1 in the present disclosure, a microlens 5 is not needed on the filters, to reduce production costs and manufacturing complexity.

### Embodiment 2

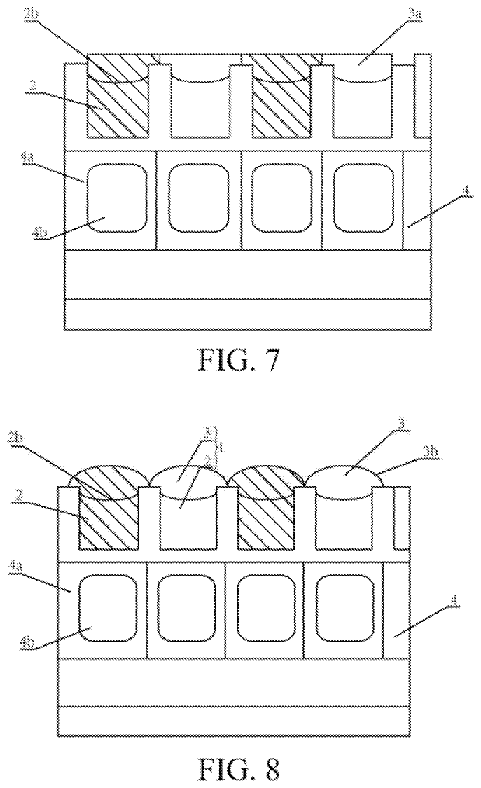

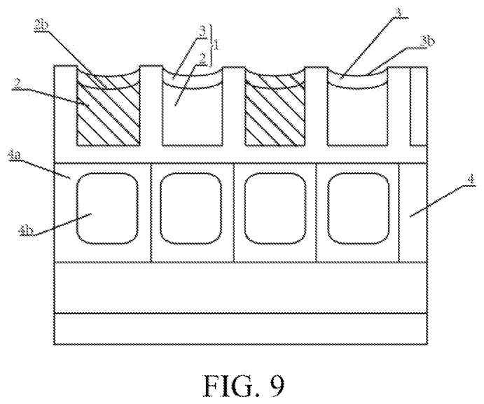

The second embodiment of the present disclosure further provides a double-layer color filter 1. Referring to FIG. 2, FIG. 8, and FIG. 9, the layer containing double-layer color filters 1 for an image sensor is disposed on a solid-state image device 4 of the image sensor. Each of the double-layer color filters 1 comprises a first filter 2 and a second filter 3. The solid-state image device 4 contains a number of pixel areas 4a. Each of the double-layer color filters 1 and each of the pixel areas 4a are aligned up for each sensing unit of the device 4. The bottom contour of the second filter 3 conforms with the top contour of the first filter 2 and is second filter is configured to focus light of the image sensor.

To increase an admitted light amount, in this embodiment, the first filter 2 has a first refractive index, the second filter 3 has a second refractive index, the second refractive index is different from the first refractive index, and the first refractive index and the second refractive index are both preferably set to be about 1.6 to 1.7.

The first filter 2 and the second filter 3 both have color filtering functions. Therefore, the double-layer filters are disposed to enhance a filtering effect on color light and reduce spectral crosstalk. The first filter 2 and the second filter 3 are formed each of which has a different refractive index from the other, so that light rays refract at the interface of the two filters, to increase the chance of light rays entering the filters, thereby enhancing light intensity of the double-layer color filters 1.

Further, in this embodiment, a first convex contour 2b having a first curve is formed on an upper surface of the first filter 2, and a second convex contour 3b having a second curve is formed on an upper surface of the second filter 3.

The curve of the first convex contour 2b and the curve of the second convex contour 3b need to be set according to the needed first refractive index and second refractive index, thereby enhancing a light concentration effect of the double-layer color filter 1 and increasing light rays received by the solid-state image device 4.

Specifically, in this embodiment, referring to FIG. 2, when the first refractive index of the first filter 2 is less than the second refractive index of the second filter 3, the first convex contour 2b and the second convex contour 3b that are raised outward are formed, the curvature radius of the first filter 2 is 0.5, and the curvature radius of the second filter 3 is set to be 0.4 to 0.6.

When the first refractive index of the first filter 2 is greater than the second refractive index, referring to FIG. 9, the first convex contour 2b and the second convex contour 3b that are pointed toward the photosensitive device 4b may be formed. Referring to FIG. 8, the first convex contour 2b pointed toward the photosensitive device 4b and the second convex contour 3b pointed outward may also be formed.

In this case, when reaching the interface of first convex contour 2b of the first filter 2, light rays are refracted to increase light rays density. When propagating to reach interface of the second convex contour 3b of the second filter 3 and ambient, the light rays are refracted out, to perform concentration of light rays for the second time, to improve light intensity.

In addition, in this embodiment, materials of the first filter 2 and the second filter 3 are different organic materials.

Different organic materials are selected, to ensure that the first filter 2 and the second filter 3 have different refractive indexes, thereby improving light density inside the filters. In addition, the organic materials have better bonding to prevent detachment of the filters.

In addition, in this embodiment, the first filter 2 and the second filter 3 disposed on the same pixel area 4a pass the same color.

The first filter 2 and the second filter 3 pass the same color, so that light of a particular color passes through the first filter 2 and the second filter 3, but light rays of other colors can be blocked or absorbed, to reduce spectral crosstalk, thereby improving performance of the image sensor.

It should be noted that in this embodiment, the color of the filter may be red, blue, or green.

Compared with existing filtered image sensor, the double-layer color filter 1 in which the first filter 2 and the second filter 3 having the second convex contour 3b are formed to have the same convex contour, so the light is focused and filtered by colors, effectively increase an entrance light, improve conversion efficiency, enhance a filtering effect on color light, and avoid occurrence of spectral crosstalk.

A person skilled in the art may understand that in the embodiment, to make readers better understand this application, many technical details are proposed. However, even if no technical details and various changes and modifications based on the foregoing embodiments are provided, the technical solutions of claims of this application can also be basically implemented. Therefore, during actual application, various changes may be made to the foregoing embodiments in forms and details without departing from the spirit and scope of the present disclosure.

1. A method for forming a double-layer color filter on a solid-state image device, comprising:
providing a photosensitive unit on a substrate;
forming a first color filter layer on the photosensitive unit;
etching the first color filter layer, to form a first filter having a first convex contour; and
forming a second color filter layer on the first convex contour of the first filter, and etching the second color filter layer, to form a second filter having a second convex contour.

2. The method for forming the double-layer color filter on the solid-state image device as in claim 1, wherein the first filter has a first refractive index, the second filter has a second refractive index, and wherein the first refractive index is different from the second refractive index.

3. The method for forming the double-layer color filter on the solid-state image device as in claim 2, wherein the first refractive index of the first filter and the second refractive index of the second filter are both in a range of 1.6 to 1.7.

4. The method for forming a double-layer color filter on the solid-state image device as in claim 1, wherein the first color filter layer is formed on the photosensitive unit by spin coating, and the second color filter layer is formed on the first convex contour of the first filter by spin coating.

5. The method for forming the double-layer color filter on the solid-state image device as in claim 1, wherein the first convex contour and the second convex contour are formed by wet etching or dry etching, and wherein an edge etch rate and a center etch rate of the first convex contour are different, and wherein an edge etch rate and a center etch rate of the second convex contour are different.

6. A double-layer color filter device for a solid-state image device, comprising a plurality of double-layer color filters mounted on photosensitive units on a substrate, wherein each of the plurality of double-layer color filters comprises: a first filter and a second filter conforming to the first filter, and wherein each of the plurality of double-layer color filters is aligned one-to-one to a pixel area of one of the photosensitive units, wherein the photosensitive units each is a solid-state image device.

7. The double-layer color filter device as in claim 6, wherein the first filter has a first refractive index, and the second filter has a second refractive index, wherein the second refractive index is different from the first refractive index.

8. The double-layer color filter device as in claim 6, wherein an upper surface of the first filter has a first curve, and an upper surface of the second filter has a second curve.

9. The double-layer color filter device as in claim 6, wherein materials of the first filter and the second filter are different organic materials.

10. The double-layer color filter device as in claim 6, wherein the first filter and the second filter aligned to a same photosensitive unit and pass the same color light.
